(19) United States
(12) Patent Application Publication
(10) Pub. No.: US 2003/0048624 A1
(43) Pub. Date: Mar. 13, 2003

(54) Low-height multi-component assemblies

(75) Inventors: Philip Damberg, Cupertino, CA (US); Craig S. Mitchell, San Jose, CA (US); John B. Riley, Dallas, TX (US); Michael Warner, San Jose, CA (US)

Correspondence Address: LERNER, DAVID, LITTENBERG,, KRUMHOLZ & MENTLIK, 600 SOUTH AVENUE WEST, WESTFIELD, NJ, 07090, US

(73) Assignee: Tessera, Inc., San Jose, CA

(21) Appl. No.: 10/224,937

(22) Filed: Aug. 21, 2002

Related U.S. Application Data
(60) Provisional application No. 60/314,035, filed on Aug. 22, 2001.

(51) Int. Cl. H05K 1/11; H05K 1/14

(52) U.S. Cl. 361/803

(57) ABSTRACT

A microelectronic assembly has a first microelectronic element, a second microelectronic element, and a structure which projects downwardly from the second microelectronic element and at least partially encompassing the first microelectronic element. The structure is at least partially flexible. A method of making a microelectronic assembly with a structure that is at least partially flexible is also disclosed.

### CROSS-REFERENCE TO RELATED APPLICATIONS

The present application claims the benefit of U.S. Provisional Application No. 60/314,035, filed Aug. 22, 2001, the disclosure of which is hereby incorporated by reference herein.

### FIELD OF THE INVENTION

The present invention relates to microelectronic assemblies having a plurality of components, and in particular, assemblies having components in a generally vertically oriented configuration, and to methods of making such assemblies.

### BACKGROUND OF THE INVENTION

Semiconductor chips are commonly provided as individual, prepackaged units. A standard chip has a flat, rectangular body with a large front face having contacts for connection to the internal circuitry of the chip. Each individual chip is typically mounted to a substrate or chip carrier, which in turn is mounted on a circuit panel such as a printed circuit board.

Considerable effort has been devoted towards development of so-called “multichip modules” in which several chips having related functions are included in a common package and attached to a common circuit panel. This approach conserves some of the space that is ordinarily wasted by individual chip packages. Certain multichip module designs utilize a single layer of chips positioned side-by-side on a surface of, a planar circuit panel. In “flip chip” designs, the front face of the chip confronts the face of the circuit panel and the contacts on the chip are bonded to the circuit panel by solder balls or other connecting elements. The “flip chip” design provides a relatively compact arrangement; each chip occupies an area of the circuit panel equal to or slightly larger than the area of the chip front face. As disclosed in commonly assigned U.S. Pat. Nos. 5,148,265 and 5,148,266, the disclosures of which are hereby incorporated by reference herein, certain innovative mounting techniques offer compactness approaching or equaling that of conventional flip chip bonding without the reliability and testing problems commonly encountered in that approach.

Various proposals have been advanced for packaging chips in a “stacked” arrangement, i.e., an arrangement where several chips are placed one on top of the other, whereby several chips can be maintained in an area of the circuit board which is less than the total area of the chip faces, such as disclosed in certain embodiments of commonly assigned U.S. Pat. No. 5,347,159, the disclosure of which is hereby incorporated by reference herein.

Commonly assigned U.S. Pat. No. 5,861,666, the disclosure of which is hereby incorporated by reference herein, teaches an assembly of semiconductor chips that are stacked vertically one on top of the other. Certain embodiments disclosed in the '666 patent provide a plurality of semiconductor chip assemblies whereby each assembly includes an interposer and a semiconductor chip mounted thereto. Each interposer also includes a plurality of leads electrically interconnecting the chip and the interposer. The assembly also includes compliant layers disposed between the chips and the interposers so as to permit relative movement of the chips and interposers to compensate for thermal expansion and contraction of the components. The subassemblies are then stacked one on top of the other so that the chips overlie one another. Although the approach set forth in the '666 patent offers useful ways of making a stacked assembly, still other methods would be desirable.

Certain assemblies include a first chip mounted on a first side and a second chip mounted on a second side of a substrate. The substrate forms connections with a circuit board so that one of the chips is disposed between the substrate and the circuit board.

Stacked chip assemblies should deal effectively with the problems associated with heat generation in stacked chips. Chips dissipate electrical power as heat during operation. Consequently, the assembly undergoes substantial thermal expansion and contraction during operation. This, in turn, can impose significant mechanical stress on the interconnecting arrangements and on the mountings that physically retain the chips. Moreover, the assembly should be simple, reliable and easily fabricated in a cost-effective manner.

### SUMMARY OF THE INVENTION

The present invention meets these needs.

In one aspect of the present invention, a packaged chip assembly adapted to be mounted to a circuit panel comprises a first microelectronic element and a second microelectronic element disposed above the first microelectronic element and connected thereto. The second microelectronic element overlies the first microelectronic element and projects outwardly beyond the first microelectronic element. A structure is connected to the second microelectronic element so that the structure projects downwardly from the second microelectronic element. The structure at least partially encompasses the first microelectronic element and has mounting terminals disposed below the first microelectronic element for mounting the assembly to an external element. The structure is at least partially flexible.

The structure connects the assembly to an external element, supporting the assembly above the external element, while providing flexibility for adapting to mechanical stresses. In certain preferred embodiments, the second microelectronic element has a front surface that projects outwardly beyond the first microelectronic element. However, the second microelectronic element need not project outwardly beyond the first microelectronic element on all sides. The second microelectronic element overlies the first microelectronic element and a portion of the front surface projects outwardly beyond the first microelectronic element. The structure projects downwardly from the second microelectronic element and includes mounting terminals disposed below the first microelectronic element. However, the mounting terminals need not be disposed underneath the first microelectronic element. The mounting terminals may be disposed at a level below the first microelectronic element and disposed alongside the first microelectronic element.

The second microelectronic element desirably has first contacts connected to the first microelectronic element and second contacts connected to the structure. In certain embodiments, the second contacts on the second microelectronic element lie outwardly from the first contact so that the structure is disposed outwardly from the first microelectronic element. The structure desirably comprises flexible leads having first ends connected to the second contacts. The mounting terminals may comprise portions of the flexible leads that are integral with the flexible leads, or separate structures connected to the flexible leads.

In certain preferred embodiments, the structure includes a substrate connected to second ends of the leads and having terminal structures for forming connections with external elements. The substrate may have an aperture formed therein having an area greater than the area of the first microelectronic element.

In certain preferred embodiments, the first microelectronic element has first pads connected to the first contacts by a bonding material. The first pads may be exposed at a front face of the first microelectronic element. The first contacts may be exposed at a front surface of the second microelectronic element. A fill material may be disposed between the front face and the front surface so as to at least partially surround the bonding material.

The structure preferably includes a first end connected to the second microelectronic element and a second end opposite the first end. The first microelectronic element is preferably disposed between the second microelectronic element and the second end of the structure.

The first contacts of the second microelectronic element are, in certain preferred embodiments, exposed at a front surface that faces downwardly, toward the first microelectronic element. In certain preferred embodiments, the first pads of the first microelectronic element are exposed at a front face that faces upwardly, toward the second microelectronic element.

In certain preferred embodiments, the assembly includes a third microelectronic element overlying the second microelectronic element and connected to the second microelectronic element. The second microelectronic element may comprise a dielectric layer. The third microelectronic element desirably includes a front face surface that faces upwardly away from the second microelectronic element. In other embodiments, the front face surface faces downwardly, toward the second microelectronic element.

The structure desirably includes a substrate below the first microelectronic element, second microelectronic element and third microelectronic element. However, the substrate need not be disposed directly underneath the first microelectronic element. In certain preferred embodiments, the substrate is disposed at a level lower than the first microelectronic element and disposed alongside the first microelectronic element. The second microelectronic element desirably has third contacts disposed at the front surface for forming connections with the third microelectronic element. Wire bonding wires may be used to connect the contact pads of the third microelectronic element to the third contacts of the second microelectronic element. In other embodiments, leads or other conductive features are used.

In certain preferred embodiments, the second microelectronic element comprises at least one window and the wire bonding wires extend from the contact pads, through the window to the third contacts on a surface of the second microelectronic element that faces away from the third microelectronic element. In other embodiments, leads extend through the window to the third contacts exposed at a surface of the second microelectronic element that faces away from the third microelectronic element. In still further embodiments, other conductive features are connected so as to extend through the window.

The first microelectronic element may comprise a package having a dielectric layer carrying the first pad and forming the front face. In certain preferred embodiments, the front surface of the second microelectronic element faces downwardly, away from the third microelectronic element and the second microelectronic element has a rear surface facing upwardly, with the third contacts being exposed at the rear surface.

In a further aspect of the present invention, a method of making a packaged chip assembly adapted to be mounted to a circuit panel comprises providing a structure having mounting terminals for mounting the assembly to an external element. The structure is at least partially flexible. The method includes providing a first microelectronic element having a front face with first pads exposed thereat, connecting the structure to a second microelectronic element, and connecting the first microelectronic element to the second microelectronic element so that the first microelectronic element is disposed between the second microelectronic element and the mounting terminals of the structure.

The second microelectronic element desirably has a front surface with first contacts and second contacts exposed at the front surface. In certain preferred embodiments, the first microelectronic element is connected to the second microelectronic element so that the front surface faces downwardly towards the first microelectronic element and the structure projects downwardly from the second microelectronic element.

In certain preferred embodiments, the structure comprises a plurality of flexible leads connected to the second contacts. The first pads of the first microelectronic element are desirably connected to the first contacts of the second microelectronic element.

The second microelectronic element desirably overlies the first microelectronic element and a third microelectronic element is connected to the second microelectronic element. In a preferred embodiment, the third microelectronic element has a front face surface with contact pads exposed thereat and the third microelectronic element is connected so that the front face surface faces upwardly, away from the second microelectronic element.

In certain preferred embodiments, the third microelectronic element has a front face surface with a plurality of contact pads disposed thereat and the third microelectronic element is connected so that the front face surface faces downwardly, toward the second microelectronic element. The second microelectronic element may include at least one window and third contacts and the contact pads may be connected to the third contacts on a surface of the second microelectronic element facing away from the third microelectronic element.

The step of connecting the contact pads may include connecting wire bonding wires to the contact pads so that the wire bonding wires extend through the at least one window and connecting the wire bonding wires to the third contacts. The step of connecting the contact pads may include connecting leads to the contact pads so that the leads extend through the at least one window and connecting the leads to the third contacts.

In certain preferred embodiments, the step of providing a structure includes providing a plurality of leads between a first element and a second element and moving the first element and the second element with respect to one another so as to deform the leads into a vertically extensive configuration. The first element may comprise a semiconductor chip and the second element may comprise a substrate.

The structure may be connected to the second microelectronic element before the first microelectronic element is connected to the second microelectronic element. Alternatively, the structure may be connected to the second microelectronic element after the first microelectronic element is connected to the second microelectronic element.

### BRIEF DESCRIPTION OF THE DRAWINGS

These and other features, aspects and advantages of the present invention will become better understood with regard to the following description, appended claims and accompanying drawings where:

FIG. 1 is a cross-sectional view of a packaged chip assembly in accordance with an embodiment of the invention;

FIG. 2 is a bottom left perspective view of a substrate for a packaged chip assembly in accordance with the embodiment of FIG. 1;

FIG. 3 is a cross-sectional view of a sheet in a method for forming a packaged chip assembly in accordance with another embodiment;

FIG. 4 is a plan view of the sheet of FIG. 3;

FIG. 5 is a cross-sectional view of the sheet of FIGS. 3 and 4 at a later stage in a method of forming a packaged chip assembly in accordance with the embodiment of FIGS. 3-4;

FIG. 6 is a cross-sectional view of the sheet at a later stage in a method of forming a packaged chip assembly in accordance with the embodiment of FIGS. 3-5;

FIG. 7 is a detailed cross-sectional view of a portion of a structure in a packaged chip assembly in accordance with the embodiment of FIGS. 1-2;

FIG. 8 is a top right perspective view of a structure in accordance with a further embodiment of the invention;

FIG. 9 is a top right perspective view of a structure in accordance with another embodiment of the invention;

FIG. 10 is a top right perspective view of a structure in accordance with a further embodiment of the invention;

FIG. 11 is a cross-sectional view of a packaged chip assembly in accordance with yet another embodiment of the invention;

FIG. 12 is a top right perspective view of a structure in a further embodiment of the invention;

FIG. 13 is a cross-sectional view of a packaged chip assembly in yet another embodiment of the invention;

FIG. 14 is a cross-sectional view of another assembly in accordance with an embodiment of the invention;

FIG. 15 is a cross-sectional view of a further embodiment of the invention;

FIG. 16 is a bottom plan view of the packaged chip assembly of FIG. 15;

FIG. 17 is a cross-sectional view of a packaged chip assembly in another embodiment of the invention;

FIG. 18 is a cross-sectional view of a packaged chip assembly in a further embodiment of the invention;

FIG. 19 is a cross-sectional view of a packaged chip assembly in yet another embodiment of the invention;

FIG. 20 is a cross-sectional view of a packaged chip assembly in another embodiment of the invention;

FIG. 21 is a cross-sectional view of a packaged chip assembly in accordance with another embodiment of the invention; and

FIG. 22 is a cross-sectional view of a packaged chip assembly in a further embodiment of the invention.

### DETAILED DESCRIPTION

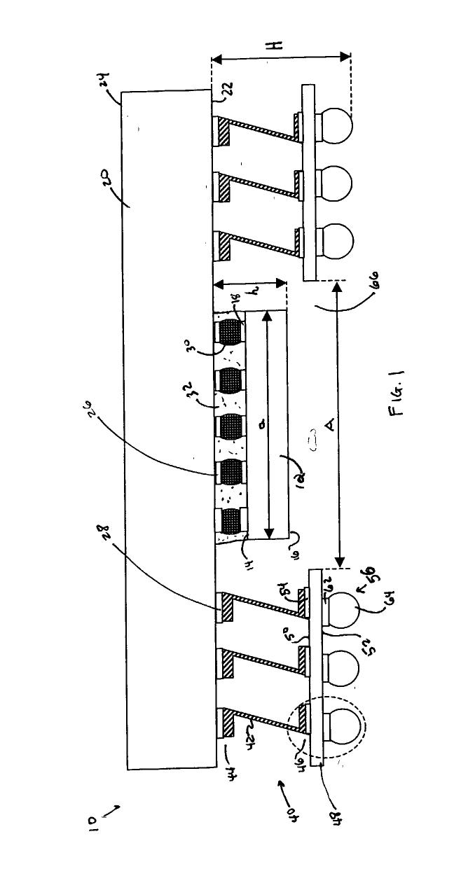

FIGS. 1-7 illustrate a packaged chip assembly 10 comprising a package in accordance with an embodiment of the present invention. A first microelectronic element 12 has a front face 14 facing upwardly and a rear face 16 facing in a downward direction. As used herein, directional terms such as “up,” “down,” “upwardly,” “downwardly,” “upper,” “lower,” etc., do not refer to any gravitational frame of reference. Rather, these directional terms are relative to the assembly.

A plurality of first pads 18 are exposed at the front face 14 and may be arranged in a central region of front face 14, a peripheral region thereof or distributed across front face 14, or in some other arrangement. First microelectronic element 12 is connected to second microelectronic element 20, which has a front surface 22 that faces in a downward, facing the first microelectronic element 12. The second microelectronic element 20 overlies the first microelectronic element 12.

Second microelectronic element 20 has a rear surface 24 facing upwardly, a plurality of first contacts 26 exposed at front surface 22 and a plurality of second contacts 28 also exposed at front surface 22. First contacts 26 and second contacts 28 are arranged so that all of the first contacts are grouped together and all of the second contacts are grouped together. In the embodiment shown in FIG. 1, for example, first contacts 26 are arranged in a central region of the second microelectronic element 20, whereas second contacts 28 are arranged at a peripheral region of the front surface 22. The first pads 18 are connected to first contacts 26, which may be accomplished using any method for interconnecting microelectronic elements in a package or assembly. For example, as shown in FIG. 1, the first pads 18 are bonded to the first contacts 26 using a bonding material 30, which may comprise solder or any other bonding material. For example, solder balls may be provided between first pads 18 and first contacts 26 and reflowed. Alternatively, solder paste or other solder material may be applied to the first pads 18, the first contacts 26, or both. The first pads 18 and first contacts 26 are brought into close alignment with one another and the solder is reflowed through the application of heat. A fill material 32, such as an epoxy silicone or other dielectric material may be disposed between the front face 14 and the front surface 22 so as to surround the solder connections. The fill material 32 may comprise an underfill such as the materials commonly used in flip chip bonding. However, methods other than solder bonding may be used to connect the first pads 18 to the first contacts 26. For example, a conductive polymer, such as metal-filled epoxy may be used. Eutectic bonding may be used. Leads or other conductive features may be attached to the first pads 18 and first contacts 26.

The packaged chip assembly includes a structure 40 which is at least partially flexible and is connected to the second contacts 28. The flexible structure desirably comprises at least one flexible element providing a space for the first microelectronic element 12. The flexible element comprises a conductive or non-conductive material. The structure 40 desirably comprises a plurality of flexible leads 42 having first ends 44 connected to the second contacts 28. The flexible leads desirably extend alongside the first microelectronic element 12 so as to provide vertical space when the leads 42 are connected to external circuitry. The flexible leads 42 have a vertically extensive configuration and are relatively flexible in the vertical and horizontal directions.

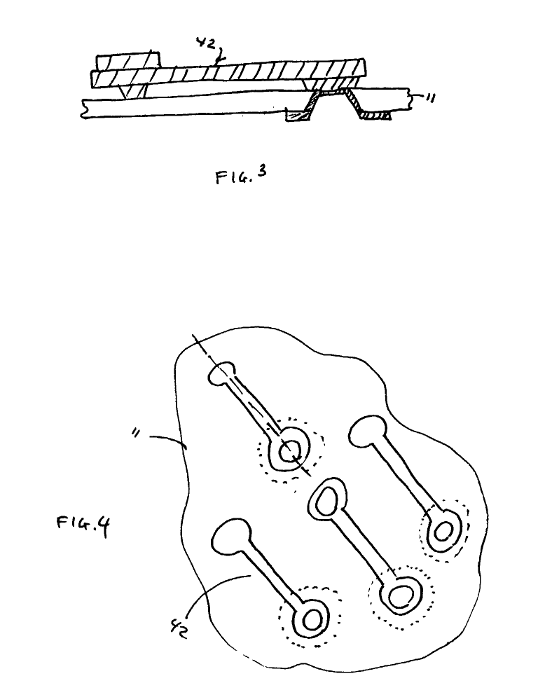

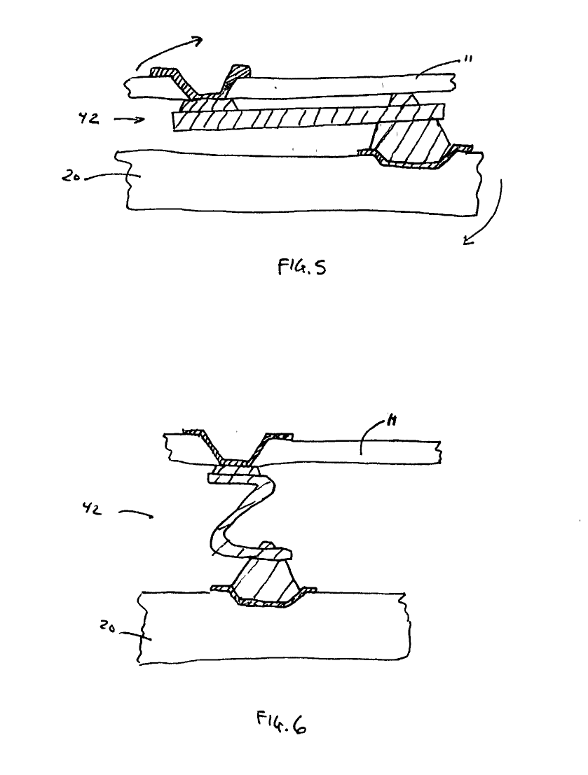

The structure 40 comprising at least one flexible element may be formed as shown in FIGS. 3-6. For example, a plurality of leads are formed on a sheet, such as sheet 11, shown in FIGS. 3 and 4. The sheet and leads may be formed substantially as disclosed in certain embodiments of U.S. Pat. No. 5,518,964, the disclosure of which is hereby incorporated by reference herein. The leads are formed on the sheet 11 and then assembled with the second microelectronic element 20. The second microelectronic element 20 and sheet are then moved in relation to one another so as to deform the leads into a vertically extensive configuration, as shown in FIGS. 5 and 6. These steps may be performed before or after assembly of the first microelectronic element 12 with the second microelectronic element 20. The sheet 11 may comprise a sacrificial part that is then removed, or the sheet 11 may remain as the substrate 48 of the assembly 10. Techniques disclosed in certain embodiments of U.S. Pat. Nos. 6,228,686; 6,191,368; 5,976,913; and 5,859,472, the disclosures of which are hereby incorporated by reference herein, may also be used. Techniques and structures disclosed in U.S. Pat. No. 6,329,607, the disclosure of which is hereby incorporated by reference herein, may also be used.

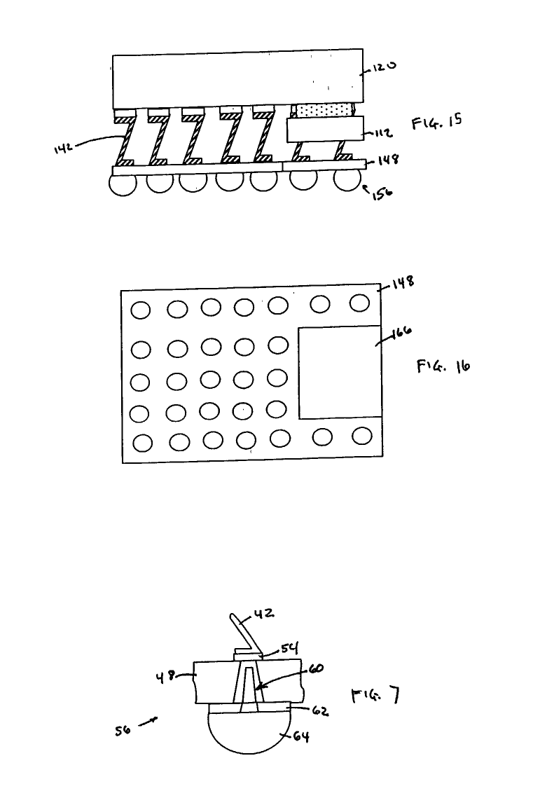

In the embodiment of FIG. 1, the structure 40 includes a substrate 48 connected to second ends 46 of the flexible leads 42. The substrate 48 has an upper side 50 facing upwardly and a lower side 52 facing downwardly. A plurality of terminal pads 54 are exposed at the upper side 50 and are connected to the second ends 46 of the flexible leads 42. A plurality of conductive features 56 are accessible at the lower side 52 of the substrate 46. The conductive features 56 may comprise any conductive structure for forming electrical connections with external circuitry. For example, the conductive features 56 may comprise vias 60 connected to the terminal pads 54 and extending through the substrate 48 from the terminal pads 54 to the lower side 52. The conductive features 56 may also include ball pads 62 at the lower side 52, also connected to the vias 60. Connections with external circuitry may be formed by providing a solder ball 64 on the ball pad 62 so that the solder ball 64 forms an electrical connection with the terminal pads 54. (See FIG. 7.) Typically, the solder ball is reflowed so as to flow into the via 60. Solid core solder balls, or any other bonding material may be used.

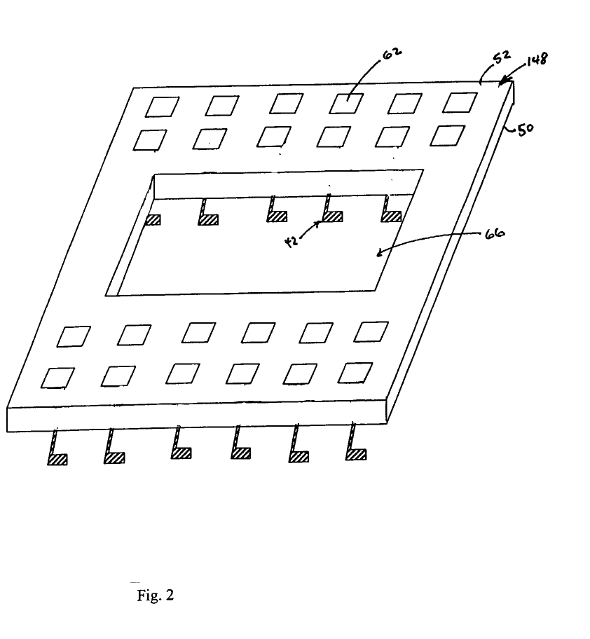

The substrate 48 has an aperture 66 with an area A that is slightly larger than the area a of the first microelectronic element 12. (See FIGS. 1 and 2). The dimensions of the structure 40 are selected so that the height H of the structure 40 is greater than the height h of the first microelectronic element 12 and its connection to the second microelectronic element 20. Thus, the first microelectronic element 12 can be accommodated in the space between the second microelectronic element 20 and a further element which is connected to the structure 40. For example, a circuit board may be connected to the conductive features 56 of the structure 40 shown in FIG. 1. The assembly has two or more microelectronic elements and a structure that is at least partially flexible and forms connections with external circuitry so that the assembly 10 has the flexibility to accommodate dimensional changes due to thermal expansion and contraction of the various components, as well as mechanical stresses from other sources.

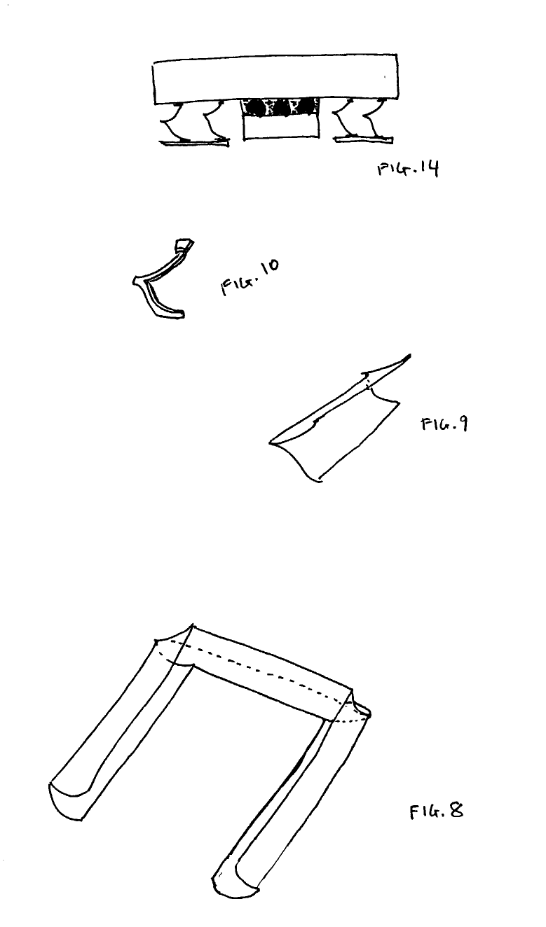

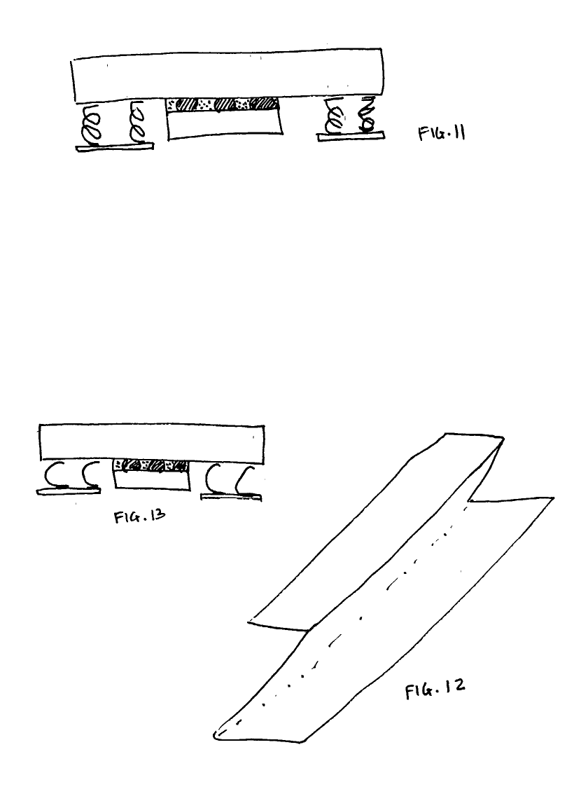

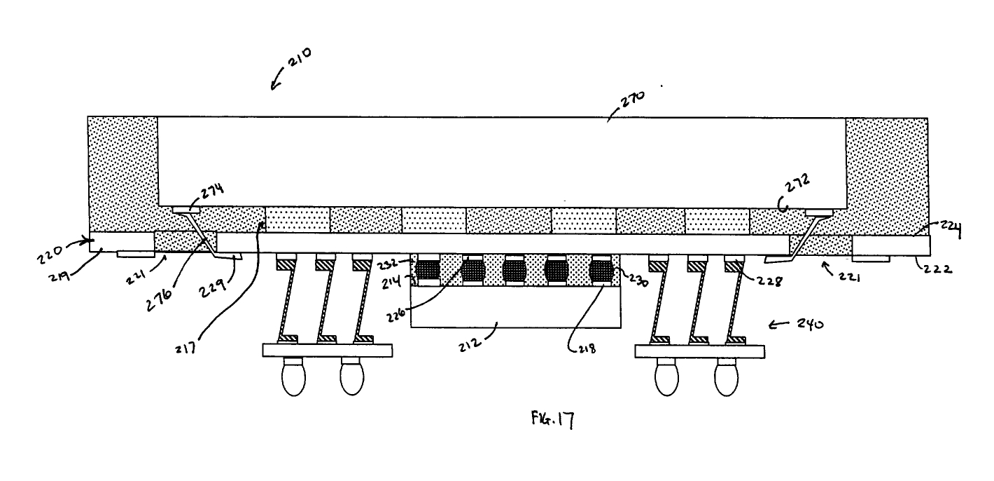

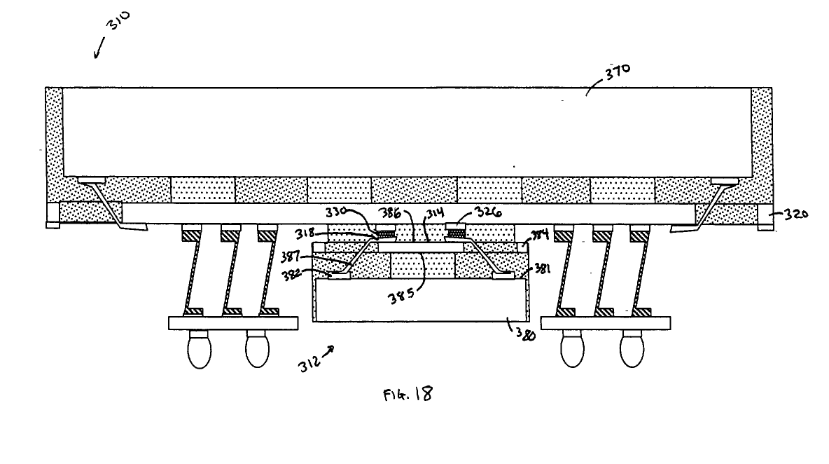

The structure 40 may comprise other flexible elements, such as one or more compliant pads connected to the front surface 22, or between front surface 22 and the upper side of the substrate 48. The structure 40 may comprise other elements of conductive, polymeric or composite materials. The structure 40 may comprise a unitary member, as shown in FIG. 8, a plurality of elongated members, as shown in FIGS. 9 and 12, or a plurality of individual members, as shown in FIGS. 10, 13 and 14. The flexible structure may incorporate members having curvilear, or any other shapes. The structure 40 may include resilient members, such as springs, as shown in FIG. 11.

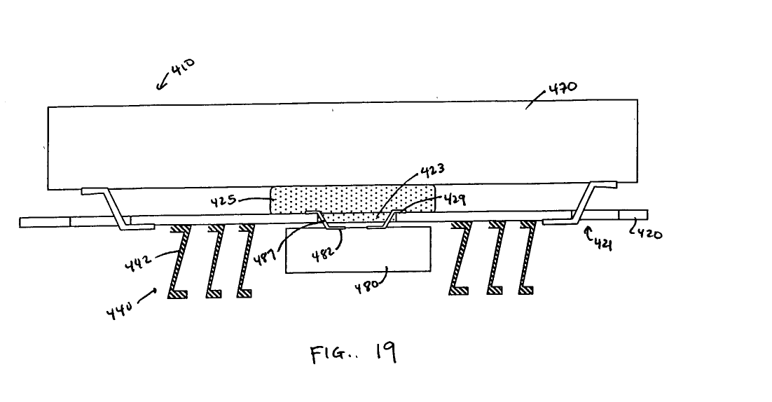

In certain preferred embodiments, the substrate 48 is omitted and the second ends of the flexible leads are directly connected to external circuitry. In embodiments including a substrate 48, the substrate may or may not include an aperture 66, as shown in FIG. 2. In other embodiments, the substrate has an aperture that is located adjacent a side of the substrate, as shown in FIGS. 15 and 16. The substrate preferably comprises a flexible material, such as polyimide or other dielectric materials. In embodiments including flexible leads 42 such leads may comprise conductive materials commonly used to form electrical connections, such as copper, gold, alloys thereof and combinations thereof. The flexible leads 42 may comprise layers of different metals or different materials. One or more of the flexible leads 42 may be provided without forming any electrical connections. Although FIG. 1 shows the conductive features 56 in alignment with the flexible leads 42, the substrate 48 may include conductive traces or other elements effectively routing the connection between the flexible lead to a conductive feature disposed some distance away from the flexible lead. The substrate may include other elements and may comprise a multi-layer structure including, for example, one or more conductive planes.

In a further embodiment of the invention, as shown in FIG. 17, a first microelectronic element 212 is connected to a second microelectronic element 220 comprising a connection component. The second microelectronic element 220 may comprise a dielectric layer having windows 221 formed therein. One or more windows may be formed at a central region of the second microelectronic element 220, a peripheral region thereof, or anywhere on the second microelectronic element 220. Second microelectronic element 220 has a front surface 222 facing in a downward direction, facing the front face 214 of the first microelectronic element 212. The second microelectronic element 220 also has a rear surface 224 facing upwardly. The first microelectronic element 212 may be connected to the second microelectronic element 220 using any method for interconnecting microelectronic elements in a package or assembly. For example, as shown in FIG. 17, the first pads 218 of the first microelectronic element 212 are connected to first contacts 226 on the front surface 222 of the second microelectronic element 220 using bonding material 230. A fill material 232 may also be disposed between the front surface 222 and the front face 214.

The second microelectronic element 220 has second contacts 228 that are connected to a structure 240, as discussed above. The packaged chip assembly 210 further includes a third microelectronic element 270 having a front face surface 272 facing downwardly, toward the second microelectronic element. A plurality of contact pads 274 are exposed at the front face surface 272. The contact pads 274 are connected to third contacts 229 on the second microelectronic element 220. The third contacts 229 may be disposed on the front surface 222 or on the rear surface 224. The third microelectronic element 270 may be connected to the second microelectronic element so that the front face surface 272 faces towards or away from the second microelectronic element 220.

In the embodiment shown in FIG. 17, the third microelectronic element 270 overlies the second microelectronic element 220 and is arranged so that the front face surface 272 faces the second microelectronic element. In the embodiment shown in FIG. 17, the contact pads 274 are connected to third contacts 229 on the front surface 222, facing away from the third microelectronic element 270. These connections are desirably formed by leads 276. Leads 276 are connected at one end to the contact pads 274 and extend through a window 221. The other ends of the leads 276 are connected to the third contacts 229. The leads 276 may comprise wire bonding wires. Wire bonding is a technique, well known in the art, in which thermocompression, ultrasonic, or thermosonic energy is used to bond an end of a wire to a feature using a tool. The tool is then used to extend the wire to a second feature for bonding. In other embodiments, the leads may be formed as disclosed in certain embodiments of WO 94/03036, U.S. Pat. Nos. 5,398,863; 5,390,844; 5,491,302; 5,148,266; 5,148,265; 5,536,909; 5,915,752; 6,054,756; 5,489,749; 5,787,581; and 5,977,618, the disclosures of which are hereby incorporated by reference herein. In certain embodiments, a component having leads with frangible sections is assembled with a semiconductor chip. The lead is forced downwardly, through the window to bond the lead to a contact on the chip, using sonic or thermosonic bonding. The frangible section of the lead is broken during bonding. However, leads without frangible sections and other techniques may be used.

The second microelectronic element 220 may comprise a dielectric component that is assembled to the third microelectronic element 270, before or after the first microelectronic element is connected to the first microelectronic element. The component includes a flexible top layer 219 and a bottom layer. In a preferred embodiment, the top layer comprises a sheet of material having a relatively high elastic modulus and the bottom layer comprises a compliant material having a relatively low elastic modulus. The component may be made as disclosed in U.S. Pat. No. 5,679,977, the disclosure of which is hereby incorporated by reference herein. In other embodiments, the second microelectronic element 220 may comprise a top sheet 219 and the bottom layer comprises a plurality of compliant elements 217. The plurality of compliant elements may be formed on the top sheet 219 utilizing screen printing, or other methods known the art, or may be formed using such methods on the front face surface 272 of the third microelectronic element 270. Such complaint pads may be formed as disclosed in certain embodiments of U.S. Pat. Nos. 5,706,174; 5,659,952; and 6,169,328, the disclosures of which are hereby incorporated by reference herein.

In a further embodiment as shown in FIG. 18, the packaged chip assembly 310 has a third microelectronic element 370 arranged with and connected to second microelectronic element 320, as discussed above. The first microelectronic element 312 comprises a semiconductor chip package having a semiconductor chip 380. The semiconductor chip 380 has a front side 381 with chip contacts 382 exposed at the front side 381. The first microelectronic element 312 also has a connection component 384 with a lower component side 385 facing downwardly, toward the semiconductor chip 380 and an upper component side 386 facing upwardly and forming the front face 314 for the first microelectronic element 312. The connection component 384 carries first pads 318 on the upper component side 386 for connection with the first contacts 326 on the second microelectronic element 320. The first pads 318 may be connected to the first contacts 326 by a bonding material 330 and the first pads 318 may be connected to the chip contacts 382 by leads 387. The bonding material may be formed as discussed above in connection with bonding material 30. The leads 387 and component 384 may be formed as discussed above in connection with leads 276 and second microelectronic element 20. Any other type of package or assembly may be incorporated in the first microelectronic element 312. The assembly 310 has a structure 340 that is at least partially flexible, as discussed above.

A second microelectronic element 420 may be assembled with a semiconductor chip 480 and connected thereto by leads 487, as shown in FIG. 19. The connection component 384 shown in FIG. 18 is thereby eliminated. The second microelectronic element 420 includes windows 421 for forming connections with the third microelectronic element 470 and at least one second window 423. The semiconductor chip 480 has chip contacts 482 connected to third contacts 429 on a surface of the second microelectronic element 420 that faces upwardly, away from the semiconductor chip 480. The chip contacts 482 may be connected to the third contacts 429 by leads 487 extending through the second window 423. A fill material 425 may be disposed in the second window 423 so as to surround the leads 487. The fill material desirably comprises an elastomer or compliant material. The second microelectronic element 420 may be formed as discussed above in connection with second microelectronic element 220. The leads 487 may be formed as discussed above in connection with leads 276. The packaged chip assembly 410 shown in FIG. 19 has a structure 440, as discussed above. In a preferred embodiment, flexible leads 442 are connected to second contacts on the second microelectronic element 420. Ends of the flexible leads 442 may be directly connected to external circuitry or a substrate, such as substrate 48 in FIG. 1, may be included.

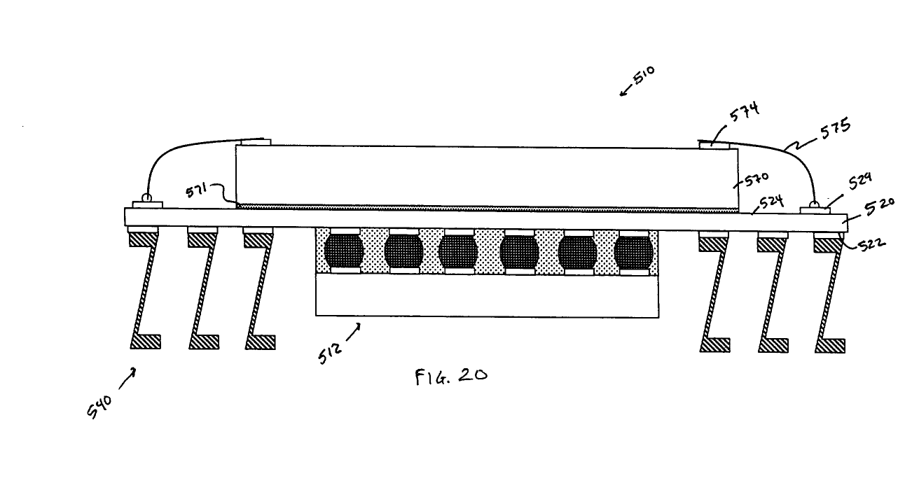

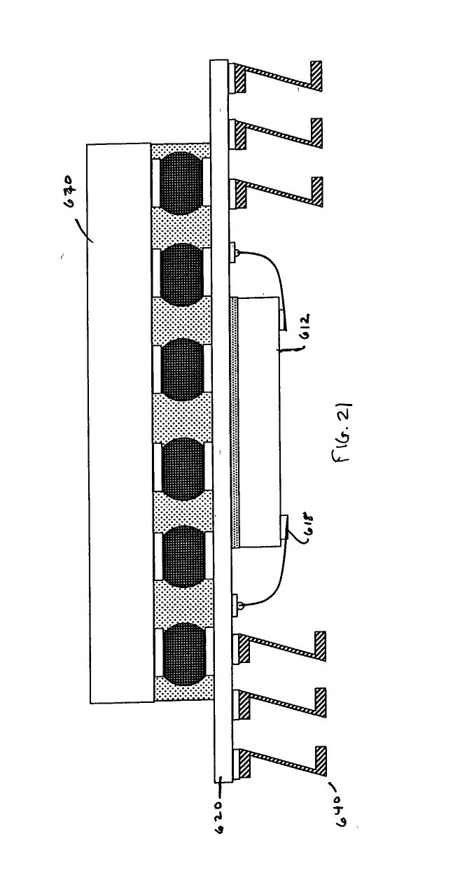

The third microelectronic element 570 may be arranged so that the contact pads 574 face upwardly, away from the second microelectronic element 520, as shown in FIG. 20. The third microelectronic element 570 is attached to the second microelectronic element 520, such as by a die attach material 571 or other adhesive. The contact pads 574 are connected to third contacts 529 on the front surface 522 or the rear surface 524 of the second microelectronic element 520. The second microelectronic element 520 may or may not include windows such as the window 221 shown in FIG. 17. In the embodiment shown in FIG. 20, the third contacts 529 are exposed at the rear surface 524 of the second microelectronic element 520 and are connected to the contact pads 574 using wire bonding wires 575. Leads, or other conductive features may also be used. The packaged chip assembly 510 includes a structure 540 connected to the second microelectronic element 520. The structure 540 creates a space for the first microelectronic element 512 adjacent the second microelectronic element 520.

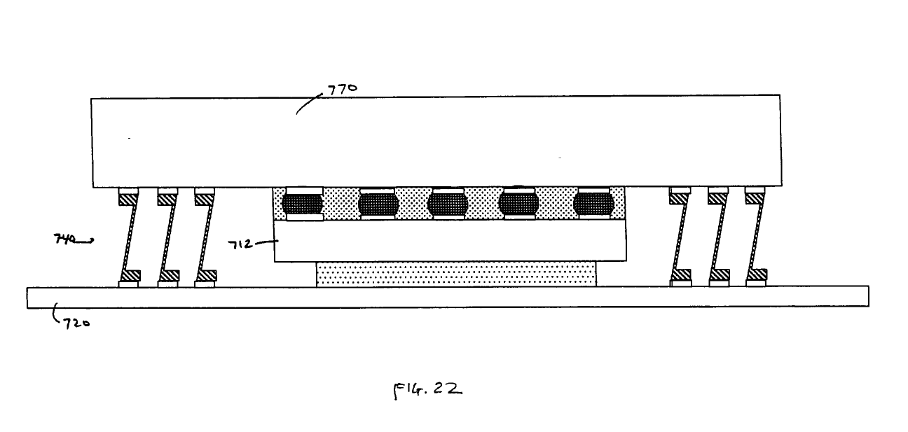

A first microelectronic element 612 may be arranged with the second microelectronic element 620 so that the first pads 618 face downwardly, away from the second microelectronic element, as shown in FIG. 21. The structure 640 creates a space for the first microelectronic element 612. As shown in FIG. 22, the structure 740 is utilized to create a space for the first microelectronic element 712 between the second and third microelectronic elements 720, 770.

Although FIGS. 1-22 depict embodiments wherein the centers of the first and second microelectronic elements are aligned, the present invention also includes embodiments wherein the first microelectronic element overlies some or all of the second microelectronic element so that the centers of such elements are not aligned. Moreover, the microelectronic elements of the present invention are not limited to single semiconductor chips. One or more semiconductor chips, semiconductor wafers, packages, assemblies, modules, components, stacked assemblies, or passive components may be assembled in vertically oriented or horizontally oriented assemblies. More than three elements may be included in the assembly.

In preferred embodiments, the assembly has a height or thickness d that is about 1 millimeter or less. In more preferable embodiments, the assembly has a thickness d of about 700 microns or less. The preferred structures of the present invention allow the formation of chip-to-chip connections having a very fine pitch. The structures for forming connections between the assembly and external circuitry desirably have a height h of 500 microns or less. Such structures allow movement relative to the circuit board or other external element to which the assembly is connected, in response to differences in thermal expansion among the elements of the assembly or other stresses. The structure allows the first microelectronic element to fit within the vertical extent of the structure. Also, the area of a the assembly approximates the area of the third microelectronic element while providing considerable space for the first, second, third, or any number of sets of contacts.

Although the invention herein has been described with reference to particular embodiments, it is to be understood that these embodiments are merely illustrative of the principles and applications of the present invention. For example, the microelectronic elements discussed above may be arranged side-by-side with one another or arranged so that their major surfaces are disposed in a vertically oriented plane. The structure need not be connected to a major surface of the second microelectronic element. The flexible structure may be disposed, in whole or in part, alongside the second microelectronic element. It is therefore to be understood that numerous modifications may be made to the illustrative embodiments and that other arrangements may be devised without departing from the spirit and scope of the present invention as described herein.

1. A packaged chip assembly adapted to be mounted to a circuit panel, comprising:
a) a first microelectronic element;
b) a second microelectronic element disposed above said first microelectronic element and connected thereto;
c) the second microelectronic element overlying the first microelectronic element and projecting outwardly beyond the first microelectronic element; and
d) a structure connected to the second microelectronic element, the structure projecting downwardly from the second microelectronic element and at least partially encompassing the first microelectronic element, the structure having mounting terminals disposed below the first microelectronic element for mounting the assembly to an external element, the structure being at least partially flexible.

2. The microelectronic assembly of claim 1, wherein the second microelectronic element has first contacts connected to the first microelectronic element and second contacts connected to the structure.

3. The microelectronic assembly of claim 2, wherein the structure comprises flexible leads having first ends connected to the second contacts.

4. The microelectronic assembly of claim 3, wherein the structure includes a substrate connected to second ends of the leads, the substrate incorporating the mounting terminals.

5. The microelectronic assembly of claim 2, wherein the first microelectronic element has first pads connected to the first contacts by a bonding material.

6. The microelectronic assembly of claim 5, wherein the first pads are exposed at a front face of the first microelectronic element, the first contacts are exposed at a front surface of the second microelectronic element, and further comprising a fill material disposed between the front face and the front surface, so as to at least partially surround the bonding material.

7. The microelectronic assembly of claim 1, wherein:
a) the structure has a first end connected to the second microelectronic element and a second end opposite form the first end; and
b) the first microelectronic element is disposed between the second microelectronic element and the second end.

8. The microelectronic assembly of claim 4, wherein the substrate has an aperture formed therein, the area of the aperture being greater than the area of the first microelectronic element.

9. The microelectronic assembly of claim 2, wherein the first contacts are exposed at a front surface of the second microelectronic element, the front surface facing downwardly, toward the first microelectronic element.

10. The microelectronic assembly of claim 9, wherein the first pads are exposed at a front face of the first microelectronic element, the front face facing upwardly, toward the second microelectronic element.

11. The microelectronic assembly of claim 2, further comprising a third microelectronic element overlying the second microelectronic element and being connected to the second microelectronic element.

12. The microelectronic assembly of claim 11, wherein the second microelectronic element comprises a dielectric layer.

13. The microelectronic assembly of claim 11, wherein the third microelectronic element overlies the second microelectronic element.

14. The microelectronic assembly of claim 11, wherein the third microelectronic element has a front face surface that faces upwardly, away from the second microelectronic element.

15. The microelectronic assembly of claim 11, wherein the third microelectronic element has a front face surface that faces downwardly, toward the second microelectronic element.

16. The microelectronic assembly of claim 11, wherein the structure comprises a substrate below the first microelectronic element, second microelectronic element and third microelectronic element.

17. The microelectronic assembly of claim 11, wherein the second microelectronic element has third contacts exposed at a front surface of the second microelectronic element.

18. The microelectronic assembly of claim 17, wherein wire bonding wires connect the contact pads of the third microelectronic element to the third contacts of the second microelectronic element.

19. The microelectronic assembly of claim 18, wherein the second microelectronic element comprises at least one window and the wire bonding wires extend from the contact pads, through the window to the third contacts on the front surface, the front surface facing away from the third microelectronic element.

20. The microelectronic assembly of claim 17, wherein the second microelectronic element comprises a window and leads are connected to the contact pads, extend through the window, and are connected to the third contacts.

21. The microelectronic assembly of claim 1, wherein the first microelectronic element comprises a package having a dielectric layer carrying first pads and forming the front face.

22. The microelectronic assembly of claim 17, wherein the front surface of the second microelectronic element faces downwardly, away from the third microelectronic element, the second microelectronic element having a rear surface facing upwardly, the third contacts being exposed at the rear surface.

23. The microelectronic assembly of claim 2, wherein the second contacts lie outwardly from the first contacts so that the structure is disposed outwardly from the first microelectronic element.

24. A method of making a packaged chip assembly adapted to be mounted to a circuit panel, comprising:
a) providing a structure having mounting terminals for mounting the assembly to an external element, the structure being at least partially flexible;
b) providing a first microelectronic element having a front face with first pads exposed thereat;
c) connecting the structure to a second microelectronic element; and
d) connecting the first microelectronic element to the second microelectronic element so that the first microelectronic element is disposed between the second microelectronic element and the mounting terminals of the structure.

25. The method of claim 24, wherein the second microelectronic element has a front surface with first contacts and second contacts exposed at the front surface and the first microelectronic element is connected to the second microelectronic element so that the front surface faces downwardly towards the first microelectronic element and the structure projects downwardly from the second microelectronic element.

26. The method of claim 25, wherein the structure comprises a plurality of flexible leads connected to the second contacts.

27. The method of claim 26, wherein the first pads of the first microelectronic element are connected to the first contacts of the second microelectronic element.

28. The method of claim 24, wherein the second microelectronic element overlies the first microelectronic element and further comprising connecting a third microelectronic element to the second microelectronic element.

29. The method of claim 28, wherein the third microelectronic element has a front face surface with contact pads exposed thereat and the third microelectronic element is connected so that the front face surface faces upwardly, away from the second microelectronic element.

30. The method of claim 29, wherein the third microelectronic element has a front face surface with a plurality of contact pads disposed thereat and the third microelectronic element is connected so that the front face surface faces downwardly, toward the second microelectronic element.

31. The method of claim 30, wherein the second microelectronic element includes at least one window and third contacts and further comprising connecting the contact pads to the third contacts on a surface of the second microelectronic element facing away from the third microelectronic element.

32. The method of claim 31, wherein the step of connecting the contact pads includes connecting wire bonding wires to the contact pads so that the wire bonding wires extend through the at least one window and connecting the wire bonding wires to the third contacts.

33. The method of claim 31, wherein the step of connecting the contact pads includes connecting leads to the contact pads so that the leads extend through the at least one window and connecting the leads to the third contacts.

34. The method of claim 24, wherein the step of providing a structure includes providing a plurality of leads between a first element and a second element and moving the first element and the second element with respect to one another so as to deform the leads into a vertically extensive configuration.

35. The method of claim 34, wherein the first element comprises a semiconductor chip and the second element comprises a substrate.

36. The method of claim 24, wherein the structure is connected to the second microelectronic element before the first microelectronic element is connected to the second microelectronic element.

37. The method of claim 24, wherein the structure is connected to the second microelectronic element after the first microelectronic element is connected to the second microelectronic element.
